(19) United States
(12) Patent Application Publication
(10) Pub. No.: US 2026/0305341 A1
(43) Pub. Date: Oct. 1, 2026

(54) SEMICONDUCTOR PACKAGE STRUCTURE, HEAT DISSIPATION MATERIAL, AND MANUFACTURING METHOD THEREOF

(71) Applicant: Metal Industries Research & Development Centre, Kaohsiung (TW)

(72) Inventors: Yu-Lung Huang, Taichung City (TW); Yu-Han Chen, Chiayi County (TW); Yu-Ting Lyu, Kaohsiung City (TW); Cheng-Yi Liu, Taoyuan City (TW); Zhang Yuan Luo, Taipei City (TW)

(73) Assignee: Metal Industries Research & Development Centre, Kaohsiung (TW)

(21) Appl. No.: 19/389,066

(22) Filed: Nov. 14, 2025

(30) Foreign Application Priority Data
Mar. 28, 2025 (TW) 114112050
Mar. 28, 2025 (TW) 114112051

(51) Int. Cl. H01L 23/373; H01L 23/00; H01L 23/367

(52) U.S. Cl. CPC H10W 40/258; H10W 40/228; H10W 42/121; H10W 72/325; H10W 72/352; H10W 72/353; H10W 90/724; H10W 90/736

(57) ABSTRACT

The present disclosure relates to a heat dissipation material and a semiconductor package structure. The heat dissipation material includes a liquid multi-component alloy and a gallium-copper intermetallic powder. The liquid multi-component alloy includes 55 wt % to 79.9 wt % of gallium, 15 wt % to 25 wt % of indium, and 5 wt % to 25 wt % of tin. The gallium-copper intermetallic powder is distributed in the liquid multi-element alloy.

### CROSS-REFERENCE TO RELATED APPLICATION

This application claims the priority benefit of Taiwan application serial no. 114112050 filed on Mar. 28, 2025 and Taiwan application serial no. 114112051, filed on Mar. 28, 2025. The entirety of each of the above-mentioned patent applications are hereby incorporated by reference herein and made a part of this specification.

### BACKGROUND

### Technical Field

The present invention relates to a semiconductor package structure, a heat dissipation material, and a manufacturing method thereof.

### Related Art

With the rapid development of technologies such as smartphones, Internet of Things (IoT) devices, 5G networks, and artificial intelligence, the global demand for high-performance semiconductor chips continues to rise, thereby driving significant growth in the semiconductor chip package market. As modern electronic devices trend toward high computing capability and miniaturized design, semiconductor chips generate substantial heat during high-power operation. If this heat cannot be effectively conducted and dissipated in a timely manner, it will cause the internal temperature of the chip to rise sharply, thereby affecting its computing performance and stability, and even significantly shortening its service life. Therefore, enhancing the heat dissipation performance of semiconductor packages has become a critical technical issue, directly affecting the performance and market competitiveness of devices.

To effectively solve the challenge of thermal energy conduction inside semiconductor chips, thermal interface material (TIM) plays a crucial role. TIM is primarily used to fill the minute gaps between chips and heat dissipation components (such as heat sinks, heat dissipation substrates, or package materials) to reduce thermal resistance and enhance thermal conduction efficiency. As the computing capability of chips continues to improve, the requirements for thermal conductivity performance, material stability, and reliability of TIM are also becoming increasingly high. Therefore, developing high-performance TIM has become an important research direction for enhancing the thermal performance of semiconductor packages, having a critical impact on ensuring efficient operation of electronic devices and extending chip service life.

### SUMMARY

The present invention provides a heat dissipation material and semiconductor device that can effectively prevent liquid multi-component alloy from shifting or overflowing to non-target areas, while reducing the impact caused by solidification of liquid thermal interface materials over time, ensuring long-term stable thermal performance.

Some embodiments of the present invention involve a heat dissipation material including a liquid multi-component alloy and gallium-copper intermetallic powder. The liquid multi-component alloy includes 55 wt % to 79.9 wt % of gallium, 15 wt % to 25 wt % of indium, and 5 wt % to 25 wt % of tin. The gallium-copper intermetallic powder is distributed in the liquid multi-component alloy.

In some embodiments, the liquid multi-component alloy further includes 0.05 wt % to 5 wt % of bismuth.

In some embodiments, the heat dissipation material includes 1 wt % to 50 wt % of the gallium-copper intermetallic powder.

In some embodiments, the heat dissipation material further includes diamond powder.

In some embodiments, the heat dissipation material includes 0.05 wt % to 5 wt % of the diamond powder.

In some embodiments, the gallium-copper intermetallic powder has an average particle size ranging from 35 micrometers to 45 micrometers.

In some embodiments, the viscosity of the heat dissipation material is 1000 cps to 10000 cps.

Some embodiments of the present invention involve a semiconductor package structure including a semiconductor die and a heat dissipation material layer. The heat dissipation material layer is located on the semiconductor die and includes a liquid multi-component alloy and gallium-copper intermetallic powder. The liquid multi-component alloy includes 55 wt % to 79.9 wt % of gallium, 15 wt % to 25 wt % of indium, and 5 wt % to 25 wt % of tin. The gallium-copper intermetallic powder is distributed in the liquid multi-component alloy.

In some embodiments, the semiconductor package structure further includes a heat spreader lid. The heat spreader lid is located on the heat dissipation material layer, and the heat dissipation material is located between the heat spreader lid and the semiconductor die.

Some embodiments of the present invention involve a method for manufacturing heat dissipation material, including the following steps. Gallium-copper intermetallic powder is formed; liquid multi-component alloy is formed, wherein the liquid multi-component alloy includes 55 wt % to 79.9 wt % of gallium, 15 wt % to 25 wt % of indium, and 5 wt % to 25 wt % of tin; the gallium-copper intermetallic powder is mixed with the liquid multi-component alloy.

In some embodiments, the method for forming the liquid multi-component alloy includes heating gallium raw material, indium raw material, and tin raw material to at least partially liquefy the gallium raw material, indium raw material, and tin raw material, and mixing them together.

In some embodiments, the liquid multi-component alloy further includes 0.05 wt % to 5 wt % of bismuth.

In some embodiments, before mixing the gallium-copper intermetallic powder with the liquid multi-component alloy, the liquid multi-component alloy is cleaned with an organic solvent; after cleaning the liquid multi-component alloy with the organic solvent, oxides in the liquid multi-component alloy are removed with acid.

In some embodiments, the method for forming gallium-copper intermetallic powder includes the following steps. An interleaved stack of one or more gallium layers and one or more copper layers is formed. The one or more gallium layers and the one or more copper layers are heated to obtain a gallium-copper intermetallic layer; The gallium-copper intermetallic layer is broken and ground to obtain gallium-copper intermetallic powder, wherein the gallium-copper intermetallic powder has an average particle size ranging from 35 micrometers to 45 micrometers.

In some embodiments, the molar ratio of copper in each of the one or more copper layers to gallium in each of the one or more gallium layers is 1 to 2.

In some embodiments, each of the one or more gallium layers has a thickness of 5 to 10 millimeters.

In some embodiments, diamond powder is mixed with the liquid multi-component alloy.

Some embodiments of the present invention involve a method for manufacturing a semiconductor package structure including the following steps. The aforementioned heat dissipation material is fabricated; the heat dissipation material is applied on a semiconductor die to obtain a heat dissipation material layer; a heat spreader lid is attached to the semiconductor die, wherein the heat dissipation material layer is located between the semiconductor die and the heat spreader lid.

In some embodiments, the heat dissipation material is applied on the semiconductor die under negative pressure.

Based on the above, the heat dissipation material includes a liquid multi-component alloy and gallium-copper intermetallic powder. The gallium-copper intermetallic powder enhances the viscosity of the heat dissipation material, thereby improving the problem of the heat dissipation material shifting or overflowing to non-target areas due to fluidity. In addition, since the gallium-copper intermetallic powder has a stable structure and does not easily react further with the liquid multi-component alloy, it may reduce the influence caused by the solidification of the liquid multi-component alloy over time, ensuring long-term stable thermal performance.

### BRIEF DESCRIPTION OF THE DRAWINGS

FIG. 1A to FIG. 6 are schematic diagrams of various stages of a method for fabricating a heat dissipation material according to some embodiments of the present invention.

FIG. 7 is a flowchart of a method for fabricating a heat dissipation material according to some embodiments of the present invention.

FIG. 8 is a cross-sectional schematic diagram of a semiconductor package structure according to some embodiments of the present invention.

### DESCRIPTION OF THE EMBODIMENTS

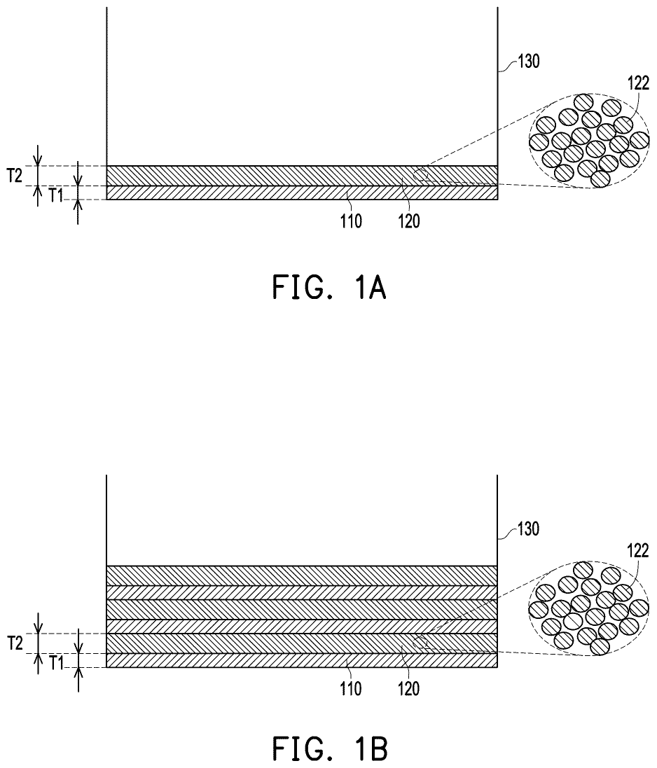

FIG. 1A to FIG. 6 are schematic diagrams of various stages of a method for fabricating a heat dissipation material according to some embodiments of the present invention. Referring to FIG. 1A and FIG. 1B, an interleaved stack of one or more gallium layers 110 and one or more copper layers 120 is formed.

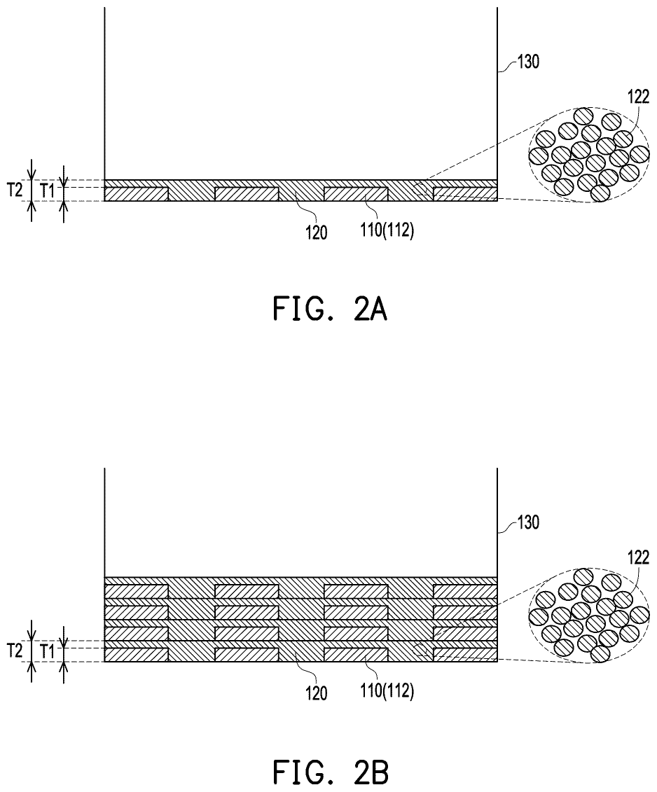

In some embodiments, the gallium layer 110 is a liquid gallium layer, but the present disclosure is not limited thereto. Since the melting point of gallium is approximately 29.76 degrees Celsius, when this step is performed below 29.76 degrees Celsius, the gallium layer may be a block-shaped gallium ingot, such as the gallium ingot 112 in FIG. 2A to FIG. 2B. In some embodiments, the thickness T1 of each gallium layer 110 is 5 millimeters to 10 millimeters.

In some embodiments, the copper layer 120 is a copper powder layer, and the copper powder 122 in the copper powder layer has an average particle size of hundreds of nanometers to tens of micrometers, such as ten micrometers, but the present disclosure is not limited thereto. In other embodiments, copper materials of other sizes may also be used as the copper layer 120. In some embodiments, the thickness T2 of each copper layer 120 is 5 millimeters to 10 millimeters.

In this embodiment, the gallium layer 110 and the copper layer 120 are alternately stacked in the crucible 130. In this embodiment, the molar ratio of copper in each copper layer 120 to gallium in each gallium layer 110 is 1 to 2.

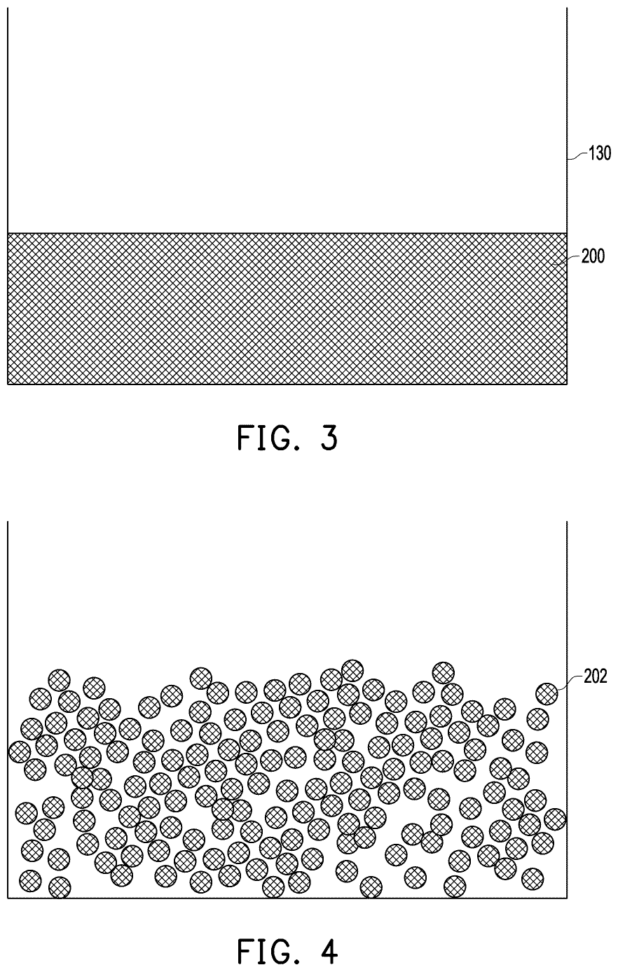

Referring to FIG. 3, the crucible 130 and the gallium layers 110 and copper layers 120 in the crucible 130 are placed into a high-temperature furnace tube. The gallium layers 110 and copper layers 120 are heated to obtain a gallium-copper intermetallic compound (CuGa₂) layer 200. In some embodiments, the gallium layers 110 and copper layers 120 are heated to 500 degrees Celsius plus or minus 3 degrees, for example, 497 degrees Celsius to 503 degrees Celsius. The solid-liquid diffusion method is utilized to accelerate the formation reaction process of the gallium-copper intermetallic compound and increase its yield.

In this embodiment, by alternately stacking the gallium layer 110 and the copper layer 120, the solid-liquid reaction interface may be increased, making the formation reaction of the intermetallic compound (IMC) more complete and avoiding residual copper powder.

Referring to FIG. 3 to FIG. 4, the gallium-copper intermetallic compound layer 200 is broken and ground to obtain gallium-copper intermetallic powder 202. In some embodiments, a ball mill, vertical roller mill, ring roller mill, Raymond mill, or other grinding machine is used to form the gallium-copper intermetallic powder 202. In this embodiment, a ball mill is used to form the gallium-copper intermetallic powder 202. Specifically, the gallium-copper intermetallic compound layer 200 is crushed and then placed into a zirconia jar containing zirconia balls of different sizes, and the gallium-copper intermetallic compound is ground through the ball mill. By adjusting the size ratio of the zirconia balls or the grinding time, gallium-copper intermetallic powder 202 with different particle sizes may be obtained. In some embodiments, the average particle size of the gallium-copper intermetallic powder 202 is 35 micrometers to 45 micrometers.

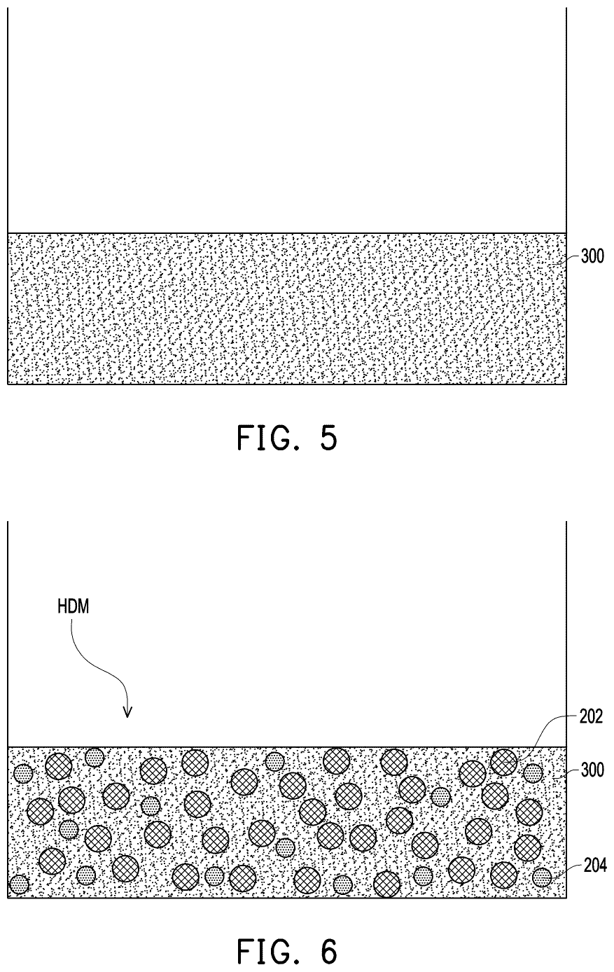

Referring to FIG. 5, a liquid multi-component alloy 300 is formed. The liquid multi-component alloy 300 is a ternary liquid alloy, quaternary liquid alloy, or quinary liquid alloy. In some embodiments, raw materials in predetermined proportions are weighed, wherein the raw materials may be metal powder and/or metal ingot.

In some embodiments, the raw materials of the liquid multi-component alloy 300 include 55 wt % to 79.9 wt % of gallium, for example, 56 wt %, 57 wt %, 58 wt %, 59 wt %, 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, or 79 wt %.

In some embodiments, the raw materials of the liquid multi-component alloy 300 include 15 wt % to 25 wt % of indium, for example, 16 wt %, 17 wt %, 18 wt %, 19 wt%, 20 wt %, 21 wt %, 22 wt %, 23 wt %, or 24 wt %.

In some embodiments, the raw materials of the liquid multi-component alloy 300 include 5 wt % to 25 wt % of tin, for example, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, or 24 wt %.

By controlling the content of gallium, indium, and tin in the liquid multi-component alloy 300, the synthesized liquid multi-component alloy 300 may be maintained in a liquid state at room temperature.

In some embodiments, the raw materials of the liquid multi-component alloy 300 optionally include 0.05 wt % to 5 wt % of bismuth, for example, 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, or 5 wt %.

Through the addition of bismuth, the entropy of the liquid multi-component alloy 300 may be reduced, the contact angle may be lowered, and the coating performance of the thermal paste may be increased.

In some embodiments, oxides on the surface of the above raw materials (gallium raw material, indium raw material, tin raw material, and optional bismuth raw material) may optionally be removed through hydrochloric acid or other acid solutions to avoid the oxides affecting subsequent processes. After acid washing the raw materials, the raw materials are dried to remove excess solution. In some embodiments, a vacuum dryer or other suitable methods are used for drying. After drying the raw materials, the raw materials are heated to liquefy at least part of the raw materials, and the raw materials are mixed. In some embodiments, a vacuum high-temperature furnace is used to heat the above raw materials to 235 degrees Celsius or above, for example, 235 degrees Celsius to 300 degrees Celsius. The liquid multi-component alloy 300 is obtained after mixing the above raw materials.

In some embodiments, the liquid multi-component alloy 300 is cleaned with an organic solvent cleaning solution, where the organic solvent is, for example, anhydrous alcohol (for example, alcohol with an alcohol concentration higher than 95 vol %) or other organic solvents. In some embodiments, after cleaning the liquid multi-component alloy 300 with the organic solvent, oxides in the liquid multi-component alloy 300 are removed with acid. For example, hydrochloric acid or other acids are used to remove oxide by-products generated during the manufacturing process of the liquid multi-component alloy 300.

In some embodiments, after acid washing the liquid multi-component alloy 300, the liquid multi-component alloy 300 is stored in anhydrous alcohol or other organic solvents.

Referring to FIG. 6, the gallium-copper intermetallic powder 202 and the liquid multi-component alloy 300 are mixed to obtain the heat dissipation material HDM. In some embodiments, the heat dissipation material HDM may also be referred to as heat dissipation paste.

In some embodiments, the liquid multi-component alloy 300 is first placed in a low oxygen solution (or referred to as oxygen-deficient solution), and the gallium-copper intermetallic powder 202 is added to the low oxygen solution. In some embodiments, the diamond powder 204 is optionally also added to the low oxygen solution. In some embodiments, the low oxygen solution is, for example, a 2M dilute hydrochloric acid solution.

Next, the liquid multi-component alloy 300, the gallium-copper intermetallic powder 202, and the optional diamond powder 204 are mixed and stirred in the low oxygen solution. Finally, the low oxygen solution is removed to obtain the heat dissipation material HDM. In some embodiments, the mixing and stirring may be performed under vacuum conditions, or vacuum may also be applied after mixing and stirring to carry out the deoxidation step. In some embodiments, the above mixing and stirring is performed through a high shear mixer.

In some embodiments, the heat dissipation material HDM includes 1 wt % to 50 wt % of the gallium-copper intermetallic powder 202, for example, 5 wt %, 10 wt %, 15 wt %, 20 wt %, 25 wt %, 30 wt %, 35 wt %, 40 wt %, or 45 wt %.

In some embodiments, the heat dissipation material HDM includes 0.05 wt % to 5 wt % of the diamond powder 204, for example, 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, or 5 wt %.

In some embodiments, through the addition of the gallium-copper intermetallic powder 202 and the optional diamond powder 204, the thermal conductivity of the heat dissipation material HDM may be effectively enhanced. In some embodiments, the thermal conductivity of the heat dissipation material HDM is, for example, 30 W/m·K to 100 W/m·K.

Based on the above, the viscosity of the heat dissipation material HDM is enhanced through the gallium-copper intermetallic powder 202, thereby improving the problem of the heat dissipation material HDM shifting or overflowing to non-target areas due to fluidity. In some embodiments, the viscosity of the heat dissipation material HDM is 1000 cps to 10000 cps.

Furthermore, since the gallium-copper intermetallic powder 202 has a stable structure and does not easily react further with the liquid multi-component alloy 300, it may reduce the impact caused by the solidification of the liquid multi-component alloy 300 over time, ensuring long-term stable heat dissipation performance. For example, if copper powder is directly mixed into a liquid multi-component alloy containing gallium, the copper powder will react with the gallium in the liquid multi-component alloy causing agglomeration, thereby degrading the heat dissipation performance.

In some embodiments, the heat dissipation material HDM may be disposed between a semiconductor die and another heat conductive component, and serves as a heat dissipation channel therebetween. The heat conductive component is, for example, a vapor chamber, a heat spreader, a heat dissipation cover, etc.

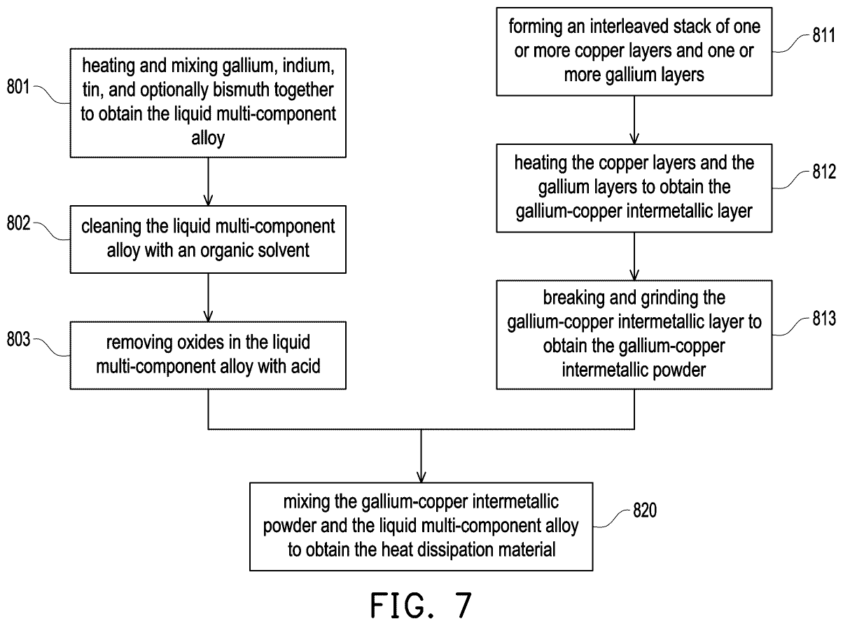

FIG. 7 is a flowchart of a method for manufacturing a heat dissipation material according to some embodiments of the present invention. Referring to step 811 of FIG. 7 and FIG. 1A to FIG. 2B, an interleaved stack of one or more copper layers 120 and one or more gallium layers 110 is formed.

Referring to step 812 of FIG. 7 and FIG. 3, the copper layers 120 and the gallium layers 110 are heated to obtain the gallium-copper intermetallic layer 200.

Referring to step 813 of FIG. 7 and FIG. 4, the gallium-copper intermetallic layer broken and ground to obtain the gallium-copper intermetallic powder 202.

Referring to step 801 of FIG. 7 and FIG. 5, gallium, indium, tin, and optionally bismuth are heated and mixed together to obtain the liquid multi-component alloy 300.

Referring to the optional step 802 of FIG. 7, the liquid multi-component alloy is cleaned with an organic solvent.

Referring to the optional step 803 of FIG. 7, oxides in the liquid multi-component alloy are removed with acid.

Referring to step 820 of FIG. 7 and FIG. 6, the gallium-copper intermetallic powder 202 and the liquid multi-component alloy 300 are mixed to obtain the heat dissipation material.

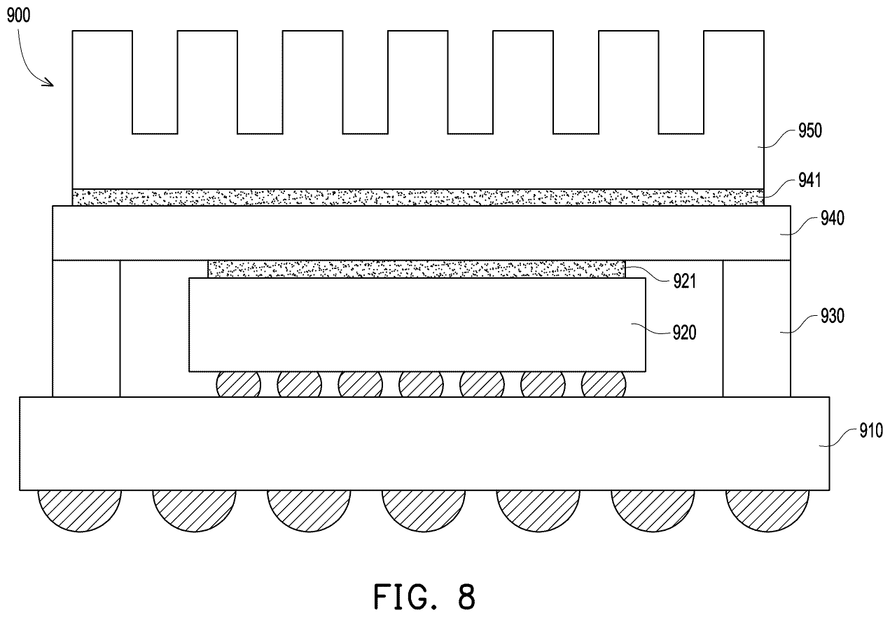

FIG. 8 is a cross-sectional schematic diagram of a semiconductor package structure 900 according to some embodiments of the present invention. Referring to FIG. 8, the semiconductor package structure 900 includes a package substrate 910, a semiconductor die 920, a first heat dissipation material layer 921, a reinforcement ring 930, a heat spreader lid 940, a second heat dissipation material layer 941, and heat dissipation fins 950.

The semiconductor die 920, for example, includes chips for high-performance computing and high-power applications.

The first heat dissipation material layer 921 is located on the semiconductor die 920. For example, the heat dissipation material HDM prepared by the embodiments described in FIG. 1A to FIG. 6 is applied on the semiconductor die 920 to obtain the first heat dissipation material layer 921. In some embodiments, the heat dissipation material HDM is applied on the semiconductor die 920 under atmosphere or negative pressure. The heat dissipation material HDM is applied on the semiconductor die 920 under negative pressure is beneficial for removing gas in the first heat dissipation material layer 921, avoiding significant expansion of the first heat dissipation material layer 921 after temperature rise.

The first heat dissipation material layer 921 and the heat dissipation material HDM prepared by the embodiments described in FIG. 1A to FIG. 6 include the same components, namely the liquid multi-component alloy 300, the gallium-copper intermetallic powder 202, and the optional diamond powder 204.

Through adding the gallium-copper intermetallic powder 202 in the liquid multi-component alloy 300, the fluidity of the heat dissipation material HDM may be reduced, making the first heat dissipation material layer 921 not easily shift or overflow to non-target areas.

The semiconductor die 920 is bonded to the package substrate 910. The reinforcement ring 930 is adhered to the substrate 910 through an adhesive layer (not shown).

The heat spreader lid 940 is attached to the semiconductor die 920, and the first heat dissipation material layer 921 is located between the heat spreader lid 940 and the semiconductor die 920. The heat spreader lid 940 is adhered to the reinforcement ring 930 through an adhesive layer (not shown).

The heat dissipation fin 950 is attached to the heat spreader lid 940 through the second heat dissipation material layer 941. The second heat dissipation material layer 941 is, for example, materials with high thermal conductivity such as heat dissipation paste, gel-based thermal adhesive or similar materials or combinations thereof. In some embodiments, the second heat dissipation material layer 941 may also be formed using the heat dissipation material HDM prepared according to the embodiments described in FIGS. 1A to 6.

FIG. 8 is only used to illustrate one implementation aspect of the heat dissipation material of the present invention, but the heat dissipation material of the present invention is not limited to being applicable only to the semiconductor package structure 900 shown in FIG. 8. The heat dissipation material of the present invention may also be applied to other types of semiconductor package structures 900.

What is claimed is:

1. A heat dissipation material, comprising:
A liquid multi-component alloy, wherein the liquid multi-component alloy comprises 55 wt % to 79.9 wt % of gallium, 15 wt % to 25 wt % of indium, and 5 wt % to 25 wt % of tin; and
gallium-copper intermetallic powder, distributed in the liquid multi-component alloy.

2. The heat dissipation material of claim 1, wherein the liquid multi-component alloy further comprises 0.05 wt % to 5 wt % of bismuth.

3. The heat dissipation material of claim 1, wherein the heat dissipation material comprises 1 wt % to 50 wt % of the gallium-copper intermetallic powder.

4. . The heat dissipation material of claim 1, further comprises diamond powder.

5. The heat dissipation material of claim 4, wherein the heat dissipation material comprises 0.05 wt % to 5 wt % of the diamond powder.

6. The heat dissipation material of claim 1, wherein the gallium-copper intermetallic powder has an average particle size ranging from 35 micrometers to 45 micrometers.

7. The heat dissipation material of claim 1, wherein the heat dissipation material has a viscosity of 1000 cps to 10000 cps.

8. A semiconductor package structure, comprising:
a semiconductor die; and
a heat dissipation material layer, located on the semiconductor die, and comprising:
a liquid multi-component alloy, wherein the liquid multi-component alloy comprises 55 wt % to 79.9 wt % of gallium, 15 wt % to 25 wt % of indium, and 5 wt % to 25 wt % of tin; and
gallium-copper intermetallic powder, distributed in the liquid multi-component alloy.

9. The semiconductor package structure of claim 8, further comprises:
a heat spreader lid, located on the heat dissipation material layer, and the heat dissipation material layer is located between the heat spreader lid and the semiconductor die.

10. A manufacturing method for a heat dissipation material, comprising:
forming gallium-copper intermetallic powder;
forming a liquid multi-component alloy, wherein the liquid multi-component alloy comprises 55 wt % to 79.9 wt % of gallium, 15 wt % to 25 wt % of indium, and 5 wt % to 25 wt % of tin; and
mixing the gallium-copper intermetallic powder with the liquid multi-component alloy.

11. The manufacturing method for the heat dissipation material of claim 10, wherein a method of forming the liquid multi-component alloy comprises:
heating gallium raw material, indium raw material, and tin raw material to at least partially liquefy the gallium raw material, the indium raw material, and the tin raw material, and mixing them together.

12. The manufacturing method for the heat dissipation material of claim 10, wherein the liquid multi-component alloy further comprises 0.05 wt % to 5 wt % of bismuth.

13. The manufacturing method for the heat dissipation material of claim 10, further comprises:
cleaning the liquid multi-component alloy with an organic solvent before mixing the gallium-copper intermetallic powder with the liquid multi-component alloy; and
removing oxides in the liquid multi-component alloy with acid after cleaning the liquid multi-component alloy with the organic solvent.

14. The manufacturing method for the heat dissipation material of claim 10, wherein a method of forming the gallium-copper intermetallic powder comprises:
forming an interleaved stack of one or more gallium layers and one or more copper layers;
heating the one or more gallium layers and the one or more copper layers to obtain a gallium-copper intermetallic layer;
breaking and grinding the gallium-copper intermetallic layer to obtain the gallium-copper intermetallic powder, wherein the gallium-copper intermetallic powder has an average particle size ranging from 35 micrometers to 45 micrometers.

15. The manufacturing method for the heat dissipation material of claim 14, wherein a molar ratio of copper in each of the one or more copper layers to gallium in each of the one or more gallium layers is 1 to 2.

16. The manufacturing method for the heat dissipation material of claim 14, wherein each of the one or more gallium layers has a thickness of 5 to 10 millimeters.

17. The manufacturing method for the heat dissipation material of claim 10, further comprises:
mixing diamond powder with the liquid multi-component alloy.

18. A manufacturing method for a semiconductor package structure, comprising:
the manufacturing method for the heat dissipation material as described in claim 10;
applying the heat dissipation material on a semiconductor die to obtain a heat dissipation material layer; and
attaching a heat spreader lid to the semiconductor die, wherein the heat dissipation material layer is located between the semiconductor die and the heat spreader lid.

19. The manufacturing method for the semiconductor package structure of claim 18, wherein the heat dissipation material is applied on the semiconductor die under negative pressure.
